(19) United States
(12) Patent Application Publication
(10) Pub. No.: US 2013/0099307 A1
(43) Pub. Date: Apr. 25, 2013

(54) SEMICONDUCTOR DEVICE HAVING METAL GATE AND MANUFACTURING METHOD THEREOF

(71) Applicants: Chi-Sheng Tseng, Kaohsiung City (TW); Jie-Ning Yang, Ping-Tung County (TW); Kuang-Hung Huang, Tainan City (TW); Yao-Chang Wang, Tainan City (TW); Po-Jui Liao, Taichung City (TW); Shih-Chieh Hsu, New Taipei City (TW)

(72) Inventors: Chi-Sheng Tseng, Kaohsiung City (TW); Jie-Ning Yang, Ping-Tung County (TW); Kuang-Hung Huang, Tainan City (TW); Yao-Chang Wang, Tainan City (TW); Po-Jui Liao, Taichung City (TW); Shih-Chieh Hsu, New Taipei City (TW)

(21) Appl. No.: 13/278,186

(22) Filed: Oct. 21, 2011

(51) Int. Cl. H01L 29/78; H01L 21/762

(52) U.S. Cl. 257/330; 438/424; 257/E29.255; 257/E21.545

(57) ABSTRACT

A manufacturing method of a semiconductor device having metal gate includes providing a substrate having a first semiconductor device and a second semiconductor device formed thereon, the first semiconductor device having a first gate trench and the second semiconductor device having a second gate trench, forming a first work function metal layer in the first gate trench, forming a second work function metal layer in the first gate trench and the second gate trench, forming a first patterned mask layer exposing portions of the second work function metal layer in the first gate trench and the second gate trench, and performing an etching process to remove the exposed second work function metal layer.

### BACKGROUND OF THE INVENTION

1. Field of the Invention

The invention relates to a semiconductor device having metal gate and manufacturing method thereof, and more particularly, to a semiconductor device having metal gate and manufacturing method integrated with the gate last process.

2. Description of the Prior Art

With a trend toward scaling down the size of the semiconductor device, work function metals are used to replace the conventional polysilicon gate to be the control electrode that competent to the high dielectric constant (high-K) gate dielectric layer. The conventional dual metal gate methods are categorized into the gate first process and the gate last process. Among the two main processes, the gate last process is able to avoid processes of high thermal budget and to provide wider material choices for the high-K gate dielectric layer and the metal gate, and thus gradually replaces the gate first process.

In the conventional gate last process, a dummy gate or a replacement gate is formed on a substrate and followed by steps of forming a conventional metal-oxide semiconductor (MOS) transistor device. Subsequently, the dummy/replacement gate is removed to form a gate trench. Then the gate trench is filled with work function metals required by different conductivity type. However, each layer formed in the gate trenches reduces an opening width of the gate trench by forming overhangs. The overhang problem makes it difficult to fill the gate trench with the other material. Serious overhang problem even results in a seam in the gate trench and makes the filling metal layer cannot be formed in the gate trench as desired. Eventually, the electrical performance of the transistor device having the metal gate is deteriorated. Furthermore, etching steps for removing the work function metal layer complementary to the required one damages the layers such as the inter layer dielectric (ILD) layer, and thus the metal materials may remain in the ILD layer and causes remnant metal defect.

Accordingly, though the gate last process is able to avoid processes of high thermal budget and to provide more material choices for the high-K gate dielectric layer and the metal gate, the gate last process still faces integrity requirements for the complicated processes, reliability requirement for the layers filling in the gate trench, and needs solution for the remnant metal defects.

### SUMMARY OF THE INVENTION

According to an aspect of the present invention, a manufacturing method of a semiconductor device having metal gate is provided. The manufacturing method includes providing a substrate having a first semiconductor device and a second semiconductor device formed thereon, the first semiconductor device having a first gate trench and the second semiconductor device having a second gate trench; forming a first work function metal layer in the first gate trench; forming a second work function metal layer in the first gate trench and the second gate trench; forming a first patterned mask layer respectively in the first gate trench and the second gate trench, the first patterned mask layer exposing a portion of the second work function metal layer; and performing an etching process to remove the exposed second work function metal layer.

According to another aspect of the present invention, a semiconductor device having metal gate is provided. The semiconductor device includes a substrate having a first semiconductor device and a second semiconductor device formed thereon, the first semiconductor device having a first gate trench and the second semiconductor device having a second gate trench; a gate dielectric layer formed in the first gate trench and the second gate trench respectively; a first U-shaped metal layer formed in the first gate trench, topmost portions of the first U-shaped metal layer are lower than an opening of the first gate trench; a second U-shaped metal layer formed in the second gate trench, topmost portions of the second U-shaped metal layer are lower than an opening of the second gate trench; and a filling metal layer formed on the first U-shaped metal layer and the second U-shaped metal layer.

According to the a semiconductor device having metal gate and manufacturing method thereof provided by the present invention, portions of the work function metal layers are removed from all the openings of the gate trenches after forming the second work function metal layer. Consequently, topmost portions of the first work function metal layer and of the second work function metal layer are all lower than the openings of the gate trenches, while the first work function metal layer and the second work function metal layer obtain a U shape. Therefore, the materials subsequently formed, such as the filling metal layer, are successfully formed in all gate trenches and thus seams are avoided. Accordingly, the semiconductor device having metal gate and manufacturing method provided by the present invention are prevented from the seam and the adverse impact rendered from the seams, and thus has the advantage of improved reliability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic drawings illustrating a manufacturing method for a semiconductor device having metal gate provided by a first preferred embodiment of the present invention, wherein

FIG. 2 is a schematic drawing in a step subsequent to FIG. 1,

FIG. 3 is a schematic drawing in a step subsequent to FIG. 2,

FIG. 4 is a schematic drawing in a step subsequent to FIG. 3,

FIG. 5 is a schematic drawing in a step subsequent to FIG. 4, and

FIG. 6 is a schematic drawing in a step subsequent to FIG. 5.

FIGS. 7-13 are drawings illustrating a manufacturing method for a semiconductor device having metal gate provided by a second preferred embodiment of the present invention, wherein

FIG. 8 is a schematic drawing in a step subsequent to FIG. 7,

FIG. 9 is a schematic drawing in a step subsequent to FIG. 8,

FIG. 10 is a schematic drawing in a step subsequent to FIG. 9,

FIG. 11 is a schematic drawing in a step subsequent to FIG. 10,

FIG. 12 is a schematic drawing in a step subsequent to FIG. 11, and

FIG. 13 is a schematic drawing in a step subsequent to FIG. 12.

FIG. 14 is a drawing illustrating a manufacturing method for a semiconductor device having metal gate provided by a modification of the present invention.

### DETAILED DESCRIPTION

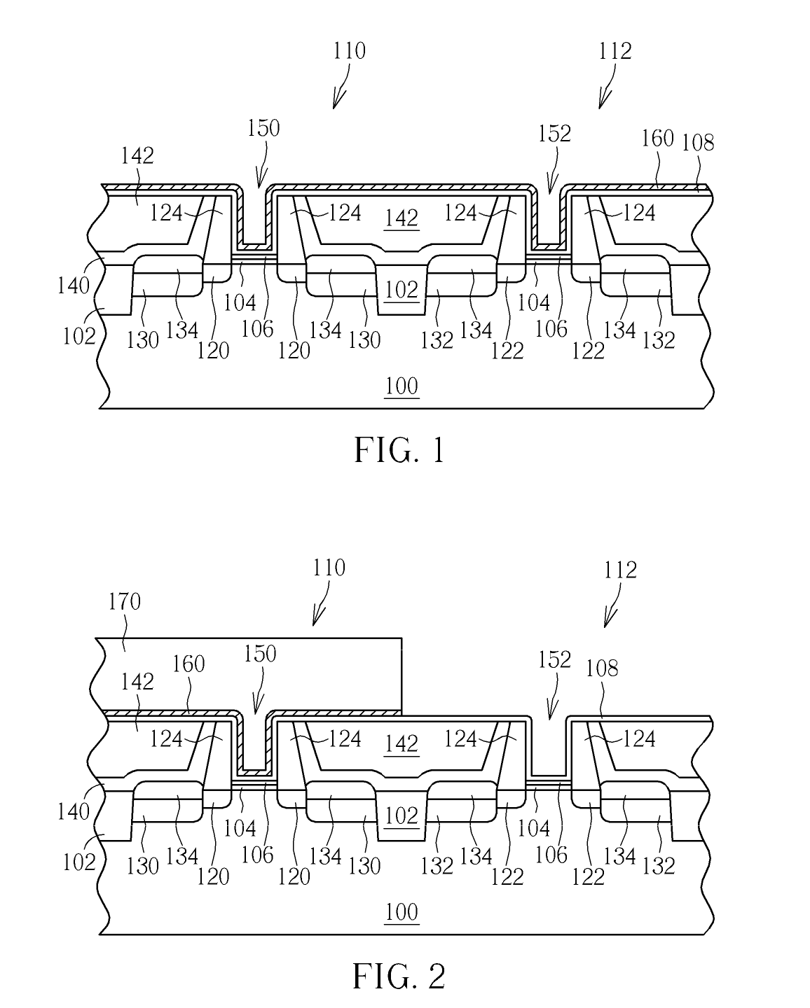

Please refer to FIGS. 1-6, which are drawings illustrating a manufacturing method for a semiconductor device having metal gate provided by a first preferred embodiment of the present invention. As shown in FIG. 1, the preferred embodiment first provides a substrate 100 such as silicon substrate, silicon-containing substrate, or silicon-on-insulator (SOI) substrate. The substrate 100 includes a first semiconductor device 110 and a second semiconductor device 112 formed thereon. A shallow trench isolation (STI) 102 is formed in the substrate 100 between the first semiconductor device 110 and the second semiconductor device 112 for providing electrical isolation. The first semiconductor device 110 includes a first conductivity type, the second semiconductor device 112 includes a second conductivity type, and the first conductivity type and the second conductivity type are complementary. In the preferred embodiment, the first conductivity type is p-type and the second conductivity type is n-type.

Please refer to FIG. 1. The first semiconductor device 110 and the second semiconductor device 112 respectively includes a gate dielectric layer 104, a bottom barrier layer 106 and a dummy gate such as a polysilicon layer (not shown). The gate dielectric layer 104 can be a conventional silicon oxide (SiO₂) layer, a high-K gate dielectric layer, or its combination. The bottom barrier layer 106 can include titanium nitride (TiN), but not limited to this. Furthermore, the first semiconductor device 110 and the second semiconductor device 112 respectively include first lightly doped drains (LDDs) 120 and second LDDs 122, a spacer 124, a first source/drain 130 and a second source/drain 132. Additionally, salicides 134 are respectively formed on the first source/drain 130 and the second source/drain 132. After forming the first semiconductor device 110 and the second semiconductor device 112, a contact etch stop layer (CESL) 140 and an inter-layer dielectric (ILD) layer 142 are sequentially formed. Since the steps and material choices for the abovementioned elements are well-known to those skilled in the art, those details are omitted herein in the interest of brevity. Furthermore, selective strain scheme (SSS) can be used in the preferred embodiment. For example, a selective epitaxial growth (SEG) method can be used to form the first source/drain 130 and the second source/drain 132.

Please still refer to FIG. 1. After forming the CESL 140 and the ILD layer 142, a planarization process is performed to remove a portion of the CESL 140 and a portion of the ILD layer 142 to expose the dummy gates of the first semiconductor device 110 and the second semiconductor device 112. Then, a suitable etching process is performed to remove the dummy gates of the first semiconductor device 110 and the second semiconductor device 112, and thus a first gate trench 150 and a second gate trench 152 are simultaneously formed in the first semiconductor device 110 and the second semiconductor device 112, respectively. It is noteworthy that the preferred embodiment is integrated with the high-k first process; therefore the gate dielectric layer 104 includes high-k materials such as rare earth metal oxide. The high-k gate dielectric layer 104 can include material selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT), and barium strontium titanate (BaₓSr₁₋ₓTiO₃, BST). Additionally, an interfacial layer (not shown) can be formed in between the high-k gate dielectric layer 104 and the substrate 100. After forming the first gate trench 150 and the second gate trench 152, an etch stop layer 108 can be formed on the bottom barrier layer 106 in both of the first gate trench 150 and the second gate trench 152. The etch stop layer 108 can include tantalum nitride (TaN), but not limited to this.

It is also noteworthy that the manufacturing method provided by the present invention can be integrated with the high-k last process; therefore the gate dielectric layer includes a conventional SiO₂ layer. After removing the polysilicon layer to form the first gate trench 150 and the second gate trench 152, the gate dielectric layer exposed in the bottoms of the first gate trench 150 and the second gate trench 152 serves as an interfacial layer (not shown). Next, a high-k gate dielectric layer 104 including materials as mentioned above is formed on the substrate 100 and followed by forming the etch stop layer 108 on the high-k gate dielectric layer 104.

Please refer to FIG. 1 again. After forming the etch stop layer 108, a chemical vapor deposition (CVD), a physical vapor deposition (PVD), or anatomic layer deposition (ALD) is performed to form a first work function metal layer 160 in the first gate trench 150 and the second gate trench 152. The first work function metal layer 160 is a p-type work function metal layer and exemplarily includes TiN, TaN, titanium carbide (TiC), tantalum carbide (TaC), tungsten carbide (WC), or aluminum titanium nitride (TiAlN), but not limited to this. In addition, the first work function metal layer 160 can be a single-layered structure or a multi-layered structure.

Please refer to FIG. 2. Next, a patterned mask layer 170, for example but not limited to a patterned photoresist layer, is formed on the substrate 100. The patterned mask layer 170 covers the first semiconductor device 110 but exposes the first work function metal layer 160 in the second semiconductor device 112. Then, a suitable etchant is used to remove the first work function metal layer 160 not cover by the patterned mask layer 170 to expose the etch stop layer 108 in the second gate trench 152. During removing the first work function metal layer 160, the etch stop layer 108 renders protection to the underneath bottom barrier layer 106, high-k gate dielectric layer 104 and ILD layer 142. After etching the exposed first work function metal layer 160, the first work function metal layer 160 remains only in the first gate trench 150 and the first semiconductor device 110 as shown in FIG. 2.

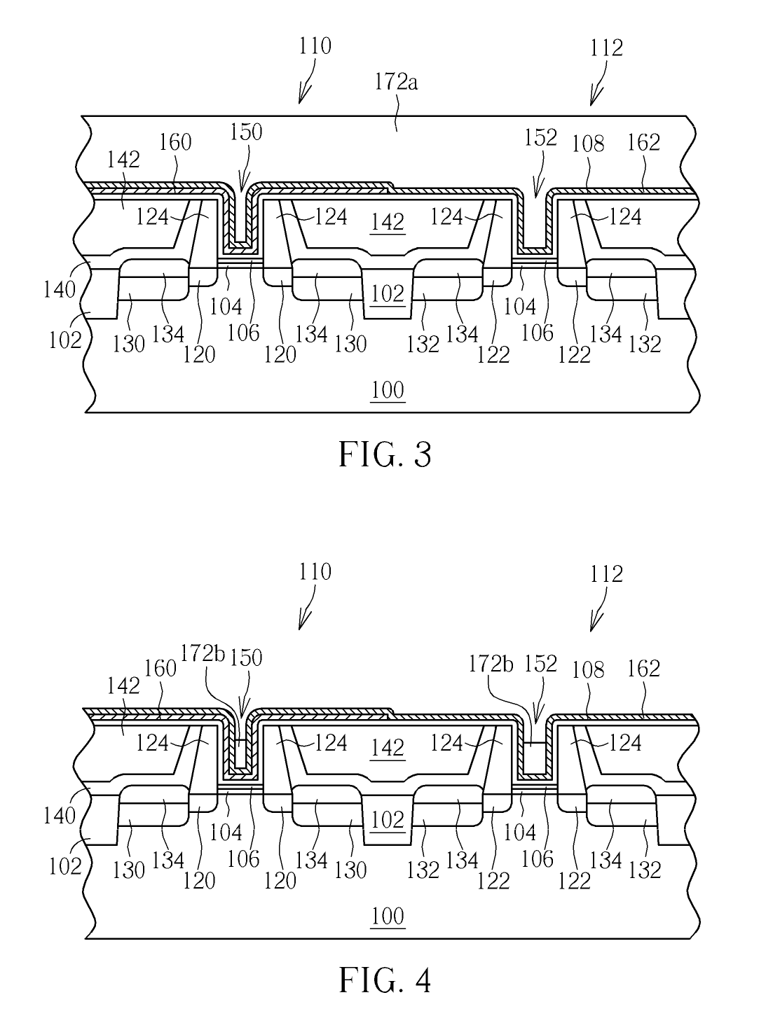

Please refer to FIG. 3. After removing the first work function metal layer 160 from the second gate trench 152 and the patterned mask layer 170, a CVD process or a PVD process is performed to form a second work function metal layer 162 on the substrate 100. The second work function metal layer 162 includes an n-type work function metal layer such as titanium aluminide (TiAl), zirconium aluminide (ZrAl), tungsten aluminide (WAl), tantalum aluminide (TaAl), or hafnium aluminide (HfAl), but not limited to this. Additionally, the second work function metal layer 162 can be a single-layered structure or a multi-layered structure. Subsequently, a mask layer 172a, for example but not limited to a photoresist layer, is formed on the second work function metal layer 162. More important, the mask layer 172a fills up the first gate trench 150 and the second gate trench 152 as shown in FIG. 3. The mask layer 172a includes materials having superior gap-filling ability, such as photoresist materials formed by spin coating, a dielectric anti-reflection coating (DARC), a light absorbing oxide (DUO), a bottom anti-reflective coating (BARC), or a sacrificial light absorbing material (SLAM), but not limited to this.

Please refer to FIG. 4. Next, the mask layer 172a is etched back to form a patterned mask layer 172b respectively in the first gate trench 150 and the second gate trench 152. A surface of the patterned mask layer 172b is lower than openings of the first gate trench 150 and the second gate trench 152. Consequently, portions of the second work function metal layer 162 are exposed.

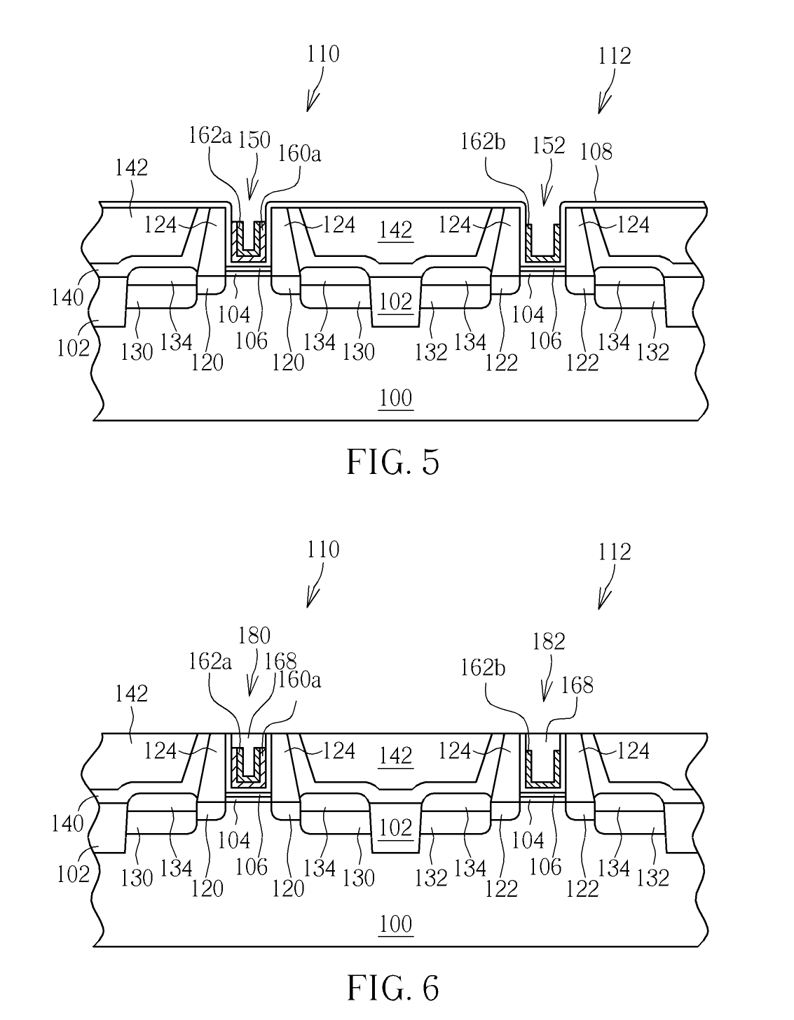

Please refer to FIG. 5. After forming the patterned mask layer 172b, an etching process is performed to remove the exposed second work function metal layer 162 and the first work function metal layer 160. The etching process is stopped at the surface of etch stop layer 108. As shown in FIG. 5, a first U-shaped metal layer 160a and a third U-shaped metal layer 162a is formed in the first gate trench 150, and simultaneously, a second U-shaped metal layer 162b is formed in the second gate trench 152. The first U-shaped metal layer 160a includes the first work function metal layer 160 and the third U-shaped metal layer 162a includes the second work function metal layer 162. The second U-shaped metal layer 162b includes the second work function metal layer 162. Subsequently, the patterned mask layer 172b is removed.

Please refer to FIG. 6. Thereafter, a filling metal layer 168 is formed in both of the first gate trench 150 and the second gate trench 152. Additionally, a top barrier layer (not shown) is preferably formed between the second work function metal layer 162 and the filling metal layer 168. The top barrier layer can include TiN, but not limited to this. The filling metal layer 168 is formed to fill up the first gate trench 150 and the second gate trench 152. The filling metal layer 168 includes materials with low resistance and superior gap-filling characteristic, such as Al, TiAl, or titanium aluminum oxide (TiAlO), but not limited to this.

Please still refer to FIG. 6. Subsequently, a planarization process, such as a chemical mechanical polishing (CMP) process is performed to remove the unnecessary filling metal layer 168 and etch stop layer 108. Consequently, a first metal gate 180 and a second metal gate 182 are obtained. In addition, the ILD layer 140 and the CESL 142 can be selectively removed and sequentially reformed on the substrate 100 for improving performance of the semiconductor devices 110, 112 in the preferred embodiment. Since the abovementioned CMP process is well-known to those skilled in the art, those details are omitted in the interest of brevity.

It is noteworthy that overhangs are always formed at the openings of the first gate trench 150 and the second gate trench 152 when forming the first work function metal layer 160 and the second work function metal layer 162. The overhangs narrow the openings of the first gate trench 150 and the second gate trench 152, and the overhang problem is even worse at the opening of the first gate trench 150 because there has both the first work function metal layer 160 and the second work function metal layer 162. Therefore, the preferred embodiment provides the etching process to simultaneously remove the overhangs formed at the openings of the first gate trench 150 and the second gate trench 152, and thus the U-shaped metal layers 160a, 162a and 162b are formed in the first gate trench 150 and the second gate trench 152. Since topmost portions of the first U-shaped metal layer 160a, the third U-shaped metal layer 162a and the second U-shaped metal layer 162b are all lower than the openings of the first gate trench 150 and the second gate trench 152, the openings of the first gate trench 150 and the second gate trench 152 remain as original. Furthermore, aspect ratios of the first gate trench 150 and the second gate trench 152 are reduced and thus the filling metal layer 168 can be successfully formed to fill up the first gate trench 150 and the second gate trench 152 without any seam. Therefore, reliability of the first semiconductor device 110 and the second semiconductor device 112 is improved.

More important, it is found that when the overhangs formed at the openings of the first gate trench 150 and the second gate trench 152 are removed respectively by different etching process, the dielectric material such as the ILD layer 142 and the CESL 140 under the boundary between the first work function metal layer 160 and the second work function metal layer 162 are severely damaged because the required etching processes (including the etching process used to remove the first work function metal layer from the second semiconductor device 112, the etching process used to remove the overhangs from the opening of the first gate trench 150, and the etching process used to remove the overhangs from the opening of the second gate trench 152). Thereafter, the filling metal layer 168 will fill up the damaged ILD layer while such metal material cannot be removed by the CMP. Consequently, the post-CMP remnant metal defects as mentioned above are resulted. As a countermeasure against to the problem, the preferred embodiment simultaneously removes the overhangs from the openings of the first gate trench 150 and the second gate trench 152 under a condition that two etching process are economized. With the etch stop layer 108 serves as a protecting layer, the ILD layer 142 and the CESL 140 under the boundary between the first work function metal layer 160 and the second work function metal layer 162 are protected and thus the post-CMP remnant metal defect are avoided. Consequently, reliability of the products is improved.

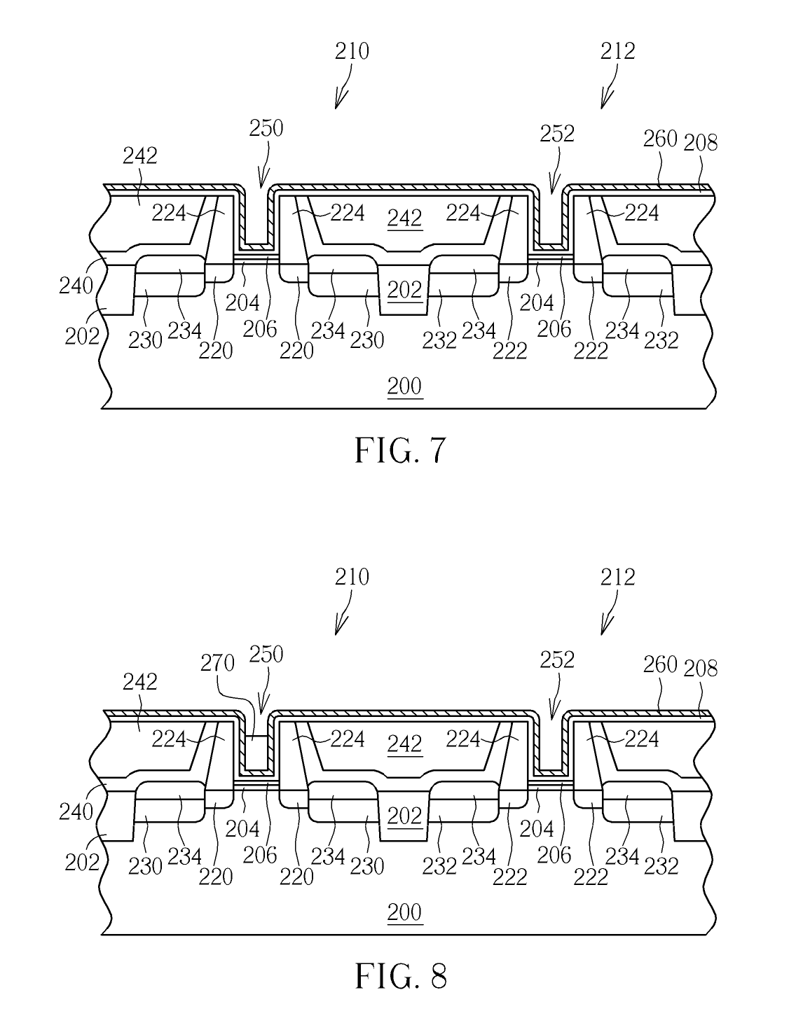

Please refer to FIGS. 7-13, which are drawings illustrating a manufacturing method for a semiconductor device having metal gate provided by a second preferred embodiment of the present invention. Please note that the elements the same in both first and second preferred embodiments can include the same material, and thus those details are omitted in the interest of brevity. As shown in FIG. 7, the preferred embodiment first provides a substrate 200. The substrate 200 includes a first semiconductor device 210 and a second semiconductor device 212 formed thereon. And a STI 202 is formed in the substrate 200 between the first semiconductor device 210 and the second semiconductor device 212 for providing electrical isolation. In the preferred embodiment, the first semiconductor device 210 includes a p-type semiconductor device and the second semiconductor device 212 includes an n-type semiconductor device.

Please still refer to FIG. 7. The first semiconductor device 210 and the second semiconductor device 212 respectively includes a gate dielectric layer 204, a bottom barrier layer 206 and a dummy gate such as a polysilicon layer (not shown). The first semiconductor device 210 and the second semiconductor device 212 respectively include first LDDs 220 and second LDDs 222, a spacer 224, a first source/drain 230 and a second source/drain 232. Additionally, salicides 234 are respectively formed on the first source/drain 230 and the second source/drain 232. After forming the first semiconductor device 210 and the second semiconductor device 212, a CESL 240 and an ILD layer 242 are sequentially formed.

Please still refer to FIG. 7. After forming the CESL 240 and the ILD layer 242, a planarization process is performed to remove a portion of the CESL 240 and a portion of the ILD layer 242 to expose the dummy gates of the first semiconductor device 210 and the second semiconductor device 212. Then, a suitable etching process is performed to remove the dummy gates of the first semiconductor device 210 and the second semiconductor device 212, and thus a first gate trench 250 and a second gate trench 252 are simultaneously formed in the first semiconductor device 210 and the second semiconductor device 212, respectively. It is noteworthy that the preferred embodiment is integrated with the high-k first process; therefore the gate dielectric layer 204 includes high-k materials. Additionally, an interfacial layer (not shown) can be formed in between the high-k gate dielectric layer 204 and the substrate 200. The preferred embodiment also can be integrated with the high-k last process. Therefore the gate dielectric layer includes a conventional SiO₂ layer and serves as the interfacial layer (not shown). After removing the polysilicon layer to form the first gate trench 250 and the second gate trench 252, the interfacial layer is exposed in the bottoms of the first gate trench 250 and the second gate trench 252. Next, a high-k gate dielectric layer 204 including materials as mentioned above is formed on the substrate 200. After forming the first gate trench 250 and the second gate trench 252, or after forming the high-k gate dielectric layer 204 in the first gate trench 250 and the second gate trench 252, an etch stop layer 208 is formed on the bottom barrier layer 206 in both of the first gate trench 250 and the second gate trench 252.

As shown in FIG. 7, after forming the etch stop layer 208, a first work function metal layer 260 is formed in the first gate trench 250 and the second gate trench 252. The first work function metal layer 260 is a p-type work function metal layer. In addition, the first work function metal layer 260 can be a single-layered structure or a multi-layered structure.

Please refer to FIG. 8. Next, a patterned mask layer 270, for example but not limited to a patterned photoresist layer, is formed on the substrate 200. It is noteworthy that the patterned mask layer 270 is formed only in the first gate trench 250, and a surface of the patterned mask layer 270 is lower than an opening of the first gate trench 250 as shown in FIG. 8.

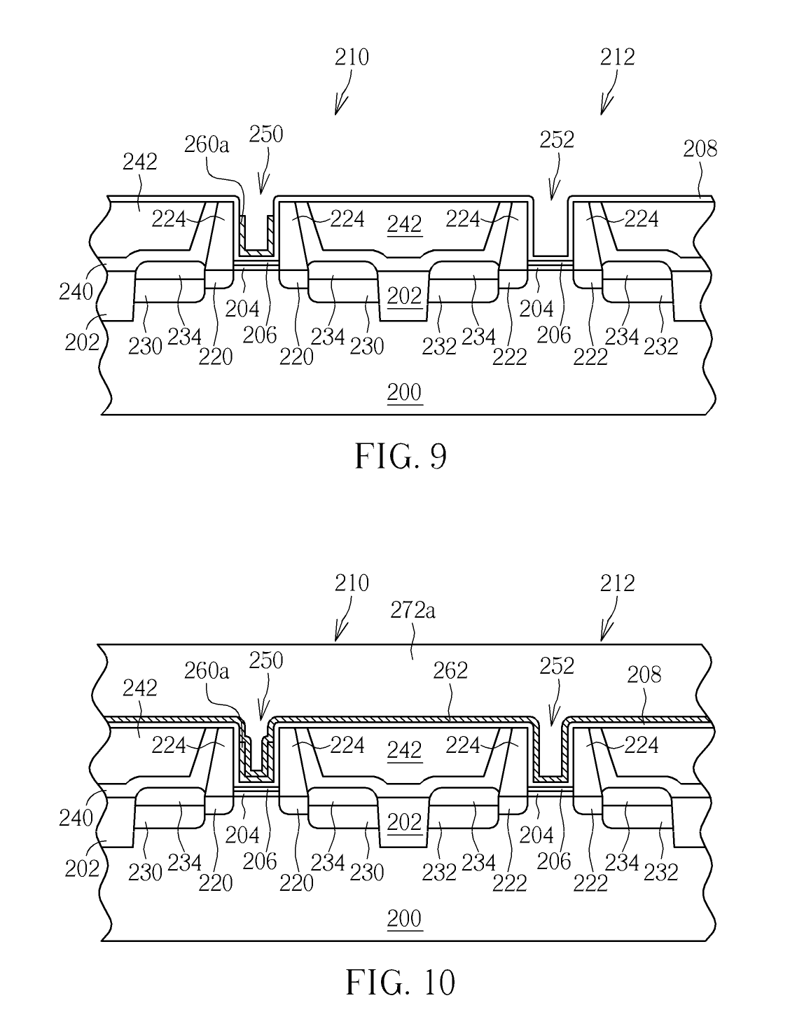

Please refer to FIG. 9. Then, a suitable etchant is used to remove the first work function metal layer 260 not cover by the patterned mask layer 270. During removing the first work function metal layer 260, the etch stop layer 208 renders protection to the underneath bottom barrier layer 206, the high-k gate dielectric layer 204, the ILD layer 242, and the CESL 240. After etching the exposed first work function metal layer 260, the first work function metal layer 260 remains only in the first gate trench 250 as shown in FIG. 9. More important, the preferred embodiment removes overhangs formed at the opening of the first gate trench 250, and thus a first U-shaped metal layer 260a is formed in the first gate trench 250. More important, topmost portions of the first U-shaped metal layer 260a are lower than the opening of the first gate trench 250. In other words, a height of the first U-shaped metal layer 260a, which covers the sidewalls of the first gate trench 250, is smaller than a depth of the first gate trench 250. Therefore, gap-filling ability of the following formed metal material is improved in accordance with the preferred embodiment.

Please refer to FIG. 10. After forming the first U-shaped metal layer 260a in the first gate trench 250, a CVD process or a PVD process is performed to form a second work function metal layer 262 on the substrate 200. The second work function metal layer 262 includes an n-type work function metal layer. Additionally, the second work function metal layer 262 can be a single-layered structure or a multi-layered structure. Subsequently, a mask layer 272a, which includes materials having superior gap-filling ability as mentioned above, is formed on the second work function metal layer 262. As shown in FIG. 10, the mask layer 272a fills up the first gate trench 250 and the second gate trench 252.

Please refer to FIG. 11. Next, the mask layer 272a is etched back to form a patterned mask layer 272b respectively in the first gate trench 250 and the second gate trench 252. A surface of the patterned mask layer 272b is lower than openings of the first gate trench 250 and the second gate trench 252. Consequently, portions of the second work function metal layer 262 are exposed.

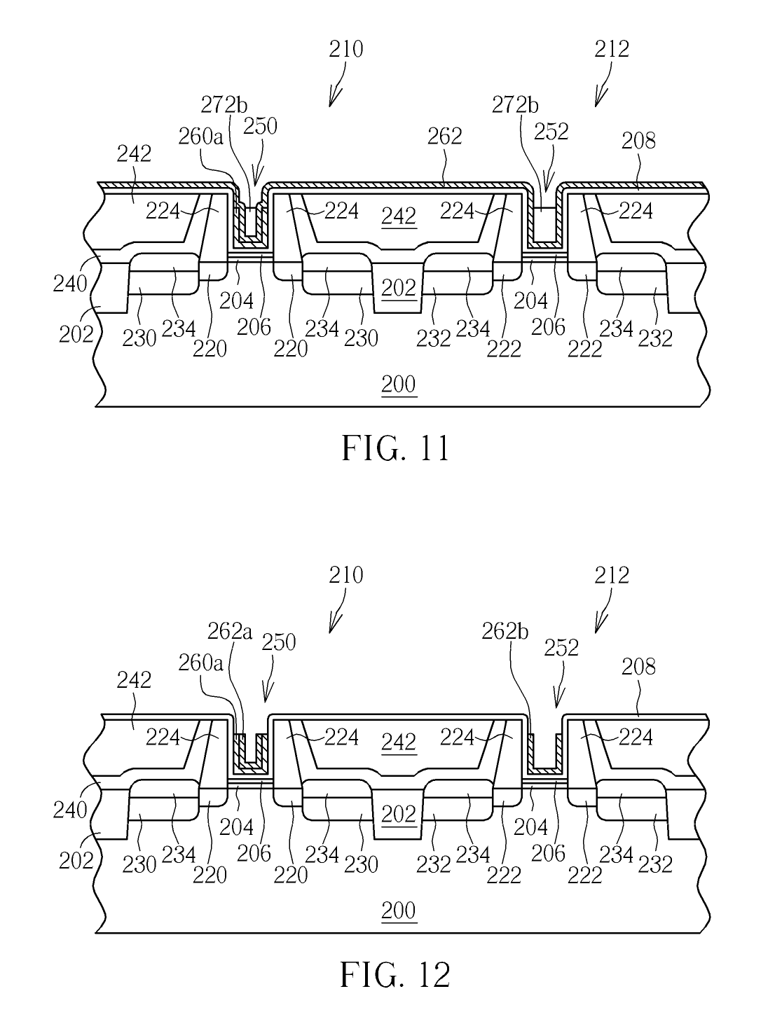

Please refer to FIG. 12. After forming the patterned mask layer 272b, an etching process is performed to remove the exposed second work function metal layer 262. The etching process is stopped at the surface of etch stop layer 208. As shown in FIG. 12, a third U-shaped metal layer 262a is formed in the first gate trench 250, and simultaneously, a second U-shaped metal layer 262b is formed in the second gate trench 252. The third U-shaped metal layer 262a includes the second work function metal layer 262. The second U-shaped metal layer 262b includes the second work function metal layer 262. Subsequently, the patterned mask layer 272b is removed.

Please refer to FIG. 14, which is a drawing illustrating a manufacturing method for a semiconductor device having metal gate provided by a modification of the present invention. It is noteworthy that the surface of the patterned mask layer 272b is coplanar or non-coplanar with the topmost portions of the first U-shaped metal layer 260a. For example, when the surface of the patterned mask layer 272b is higher than the topmost portions of the first U-shaped metal layer 260a, the second work function metal layer 262 obtains an inverted Ω shape as shown in FIG. 14. When the surface of the patterned mask layer 272b is lower than the topmost portions of the first U-shaped metal layer 260a, the second work function metal layer 262 is formed to be a U-shaped metal layer with its topmost portions still lower than the topmost portions of the first U-shaped metal layer 260a.

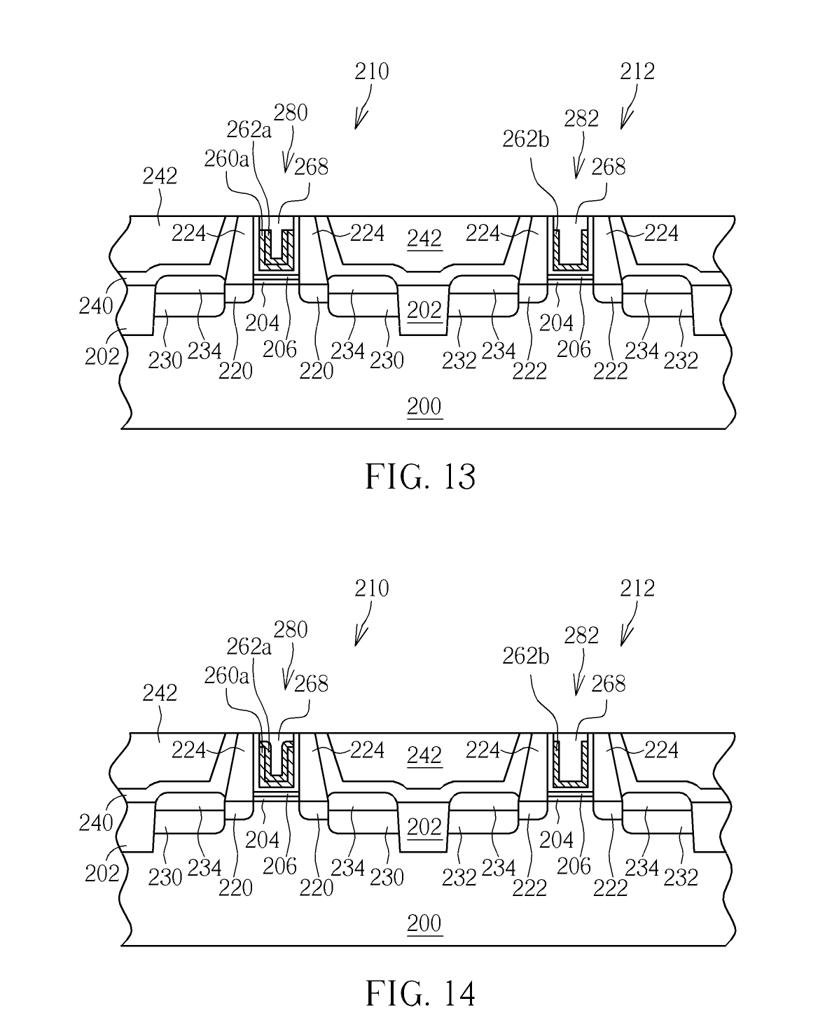

Please refer to FIG. 13. Thereafter, a filling metal layer 268 is formed in both of the first gate trench 250 and the second gate trench 252. Additionally, a top barrier layer (not shown) is preferably formed between the second work function metal layer 262 and the filling metal layer 268. The filling metal layer 268 is formed to fill up the first gate trench 250 and the second gate trench 252. The filling metal layer 168 includes materials with low resistance and superior gap-filling characteristic. Subsequently, a planarization process, such as a CMP process is performed to remove the unnecessary filling metal layer 268 and etch stop layer 208. Consequently, a first metal gate 280 and a second metal gate 282 are obtained. In addition, the ILD layer 240 and the CESL 242 can be selectively removed and sequentially reformed on the substrate 200 for improving performance of the semiconductor devices 210, 212 in the preferred embodiment. Since the abovementioned CMP process is well-known to those skilled in the art, those details are omitted in the interest of brevity.

As mentioned above, it is found that overhangs are always formed at the openings of the first gate trench 250 and the second gate trench 252 when forming the first work function metal layer 260 and the second work function metal layer 262. The overhangs narrow the openings of the first gate trench 250 and the second gate trench 252. Therefore, the preferred embodiment provides the etching processes to remove the overhangs from the openings of the first gate trench 250 and the second gate trench 252, and thus the first U-shaped metal layer 260a and the third U-shaped metal layer 262a are formed in the first gate trench 250 while the second U-shaped metal layer 262b is formed in the second gate trench 252. Since topmost portions of the first U-shaped metal layer 260a, the third U-shaped metal layer 262a and the second U-shaped metal layer 262b are all lower than the openings of the first gate trench 250 and the second gate trench 252, the openings of the first gate trench 250 and the second gate trench 252 remain as original. Furthermore, aspect ratios of the first gate trench 250 and the second gate trench 252 are reduced and thus the filling metal layer 268 can be successfully formed to fill up the first gate trench 250 and the second gate trench 252 without any seam. Therefore, reliability of the first semiconductor device 210 and the second semiconductor device 212 is improved.

Furthermore, because the overhangs composed of the first work function metal layer 260 formed at the openings of the first gate trench 250 is removed before forming the second work function metal layer 262, the gap-filling result of the second work function metal layer 262 in the first gate trench 250 and the second gate trench 252 is improved. More important, since the overhangs made of the first work function metal layer 260 is removed simultaneously with removing the unnecessary first work function metal layer 260 from the second semiconductor device 212 by the same etching process, and overhangs composed of the second work function metal layer 262 is removed by another etching process, at least one etching process is economized. As mentioned above, with the etch stop layer 208 serves as a protecting layer, the ILD layer 242 and the CESL 240 under the boundary between the first work function metal layer 260 and the second work function metal layer 262 are protected and thus the post-CMP remnant metal defect is avoided. Consequently, reliability of the products is improved.

According to the a semiconductor device having metal gate and manufacturing method thereof provided by the present invention, portions of the second work function metal layer are removed from all of the gate trench after forming the second work function metal layer under a condition that at least two etching processes are economized. Consequently, topmost portions of the first work function metal layer and the second work function metal layer are all lower than openings of gate trenches, and the first work function metal layer and the second work function metal layer obtain a U shape. Therefore, the materials subsequently formed, such as the filling metal layer, can be successfully formed in all gate trenches without any seams. Accordingly, the semiconductor device having metal gate and manufacturing method provided by the present invention are prevented from the seam and the adverse impact rendered from the seams, and thus has the advantage of improved reliability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device having metal gate comprising:
providing a substrate having a first semiconductor device and a second semiconductor device formed thereon, the first semiconductor device having a first gate trench and the second semiconductor device having a second gate trench;
forming a first work function metal layer in the first gate trench;
forming a second work function metal layer in the first gate trench and the second gate trench;
forming a first patterned mask layer respectively in the first gate trench and the second gate trench, the first patterned mask layer exposing portions of the second work function metal layer; and
performing an etching process to remove the exposed second work function metal layer.

2. The manufacturing method of a semiconductor device having metal gate according to claim 1, wherein the first semiconductor device comprises a first conductivity type, the second semiconductor device comprises a second conductivity type, and the first conductivity type and the second conductivity type are complementary.

3. The manufacturing method of a semiconductor device having metal gate according to claim 1, wherein the step of forming the first work function metal layer in the first gate trench further comprises:
forming the first work function metal layer on the substrate;
forming a second patterned mask layer on the substrate, the second patterned mask layer exposing at least the first work function metal layer in the second gate trench; and
removing the exposed first work function metal layer.

4. The manufacturing method of a semiconductor device having metal gate according to claim 3, wherein a surface of the second patterned mask layer is lower than an opening of the first gate trench.

5. The manufacturing method of a semiconductor device having metal gate according to claim 4, wherein the exposed first work function metal layer is removed to form a first U-shaped metal layer in the first gate trench.

6. The manufacturing method of a semiconductor device having metal gate according to claim 4, wherein the etching process removes the exposed second work function metal layer to simultaneously form a second U-shaped meta layer in the second gate trench and a third U-shaped metal layer in the first gate trench.

7. The manufacturing method of a semiconductor device having metal gate according to claim 6, wherein the third U-shaped metal layer covers the first U-shaped metal layer.

8. The manufacturing method of a semiconductor device having metal gate according to claim 7, wherein topmost portions of the third U-shaped metal layer and topmost portions of the first U-shaped metal layer are coplanar or non-coplanar.

9. The manufacturing method of a semiconductor device having metal gate according to claim 1, wherein the step of forming the first patterned mask layer in the first gate trench and the second gate trench further comprises:
forming a first mask layer filling up the first gate trench and the second gate trench on the substrate; and
etching back the first mask layer to form the first patterned mask layer, wherein a surface of the first patterned mask layer is lower than openings of the first gate trench and the second gate trench and exposes the portions of the second work function metal layer.

10. The manufacturing method of a semiconductor device having metal gate according to claim 1, wherein the etching process removes the exposed second work function metal layer and the first work function metal layer.

11. The manufacturing method of a semiconductor device having metal gate according to claim 10, wherein the etching process removes the exposed second work function metal layer and the first work function metal layer to simultaneously form a first U-shaped metal layer and a third U-shaped metal layer in the first gate trench and a second U-shaped metal layer in the second gate trench.

12. The manufacturing method of a semiconductor device having metal gate according to claim 11, wherein the first U-shaped metal layer comprises the first work function metal layer, the third U-shaped metal layer comprises the second work function metal layer, and the second U-shaped metal layer comprises the second work function metal layer.

13. The manufacturing method of a semiconductor device having metal gate according to claim 1, wherein the second gate trench and the first gate trench are simultaneously formed.

14. The manufacturing method of a semiconductor device having metal gate according to claim 1, further comprising forming a filling metal in the first gate trench and the second gate trench after the etching process.

15. A semiconductor device having metal gate, comprising:
a substrate having a first semiconductor device and a second semiconductor device formed thereon, the first semiconductor device having a first gate trench and the second semiconductor device having a second gate trench;
a gate dielectric layer formed in the first gate trench and the second gate trench respectively;
a first U-shaped metal layer formed in the first gate trench, topmost portions of the first U-shaped metal layer being lower than an opening of the first gate trench;
a second U-shaped metal layer formed in the second gate trench, topmost portions of the second U-shaped metal layer being lower than an opening of the second gate trench; and
a filling metal layer formed on the first U-shaped metal layer and the second U-shaped metal layer.

16. The semiconductor device having metal gate according to claim 15, wherein the gate dielectric layer comprises a high dielectric constant (high-k) gate dielectric layer.

17. The semiconductor device having metal gate according to claim 15, wherein the first U-shaped metal layer comprises a first work function metal layer.

18. The semiconductor device having metal gate according to claim 17, wherein the second U-shaped metal layer comprises a second work function metal layer.

19. The semiconductor device having metal gate according to claim 18, further comprising a third U-shaped metal layer formed between the first U-shaped metal layer and the filling metal layer, the third U-shaped metal layer covers the first U-shaped metal layer and comprises the second work function metal layer.

20. The semiconductor device having metal gate according to claim 19, wherein topmost portions of the third U-shaped metal layer and the topmost portions of the first U-shaped metal layer are coplanar or non-coplanar.
